(19) United States
(12) Patent Application Publication
(10) Pub. No.: US 2016/0309620 A1
(43) Pub. Date: Oct. 20, 2016

(54) PUMP, COOLING APPARATUS AND ELECTRONIC DEVICE

(71) Applicant: FUJITSU LIMITED, Kawasaki-shi (JP)

(72) Inventors: Tsuyoshi So, Kawasaki (JP); Hideo Kubo, Kawasaki (JP); Nobumitsu Aoki, Kawasaki (JP); Yoshinori Uzuka, Kawasaki (JP)

(73) Assignee: FUJITSU LIMITED, Kawaskai-shi (JP)

(21) Appl. No.: 15/069,088

(22) Filed: Mar. 14, 2016

(30) Foreign Application Priority Data
Apr. 14, 2015 (JP) 2015-082189

(51) Int. Cl. H05K 7/20; F04D 29/52; F04D 29/58; F04D 19/00; F04D 19/02

(52) U.S. Cl. CPC H05K 7/20272; F04D 19/002; F04D 19/02; F04D 29/582; F04D 29/522; H05K 7/20327; H05K 7/20263

(57) ABSTRACT

A pump includes: an impeller including a rotary shaft and a plurality of blades extending radially from the rotary shaft, a cutout or a hole is formed in each of the blades; a casing housing the impeller therein; an inlet provided to the casing, a thermal medium flows in the casing through the inlet; and an outlet provided to the casing, the thermal medium flows out of the casing through the outlet.

### CROSS-REFERENCE TO RELATED APPLICATION

This application is based upon and claims the benefit of priority of the prior Japanese Patent Application No. 2015-082189, filed on Apr. 14, 2015, the entire contents of which are incorporated herein by reference.

### FIELD

The embodiments disclosed herein are related to a pump, a cooling apparatus, and an electronic device.

### BACKGROUND

Recently, miniaturization and high performance are being further promoted in various electronic devices, including a computer. An electronic component mounted on the electronic device (e.g., a central processing unit (CPU)), generates a large amount of heat during the operation thereof. The temperature of the electronic component, which exceeds a permissible upper-limit temperature, may cause the reduction in processing capability, malfunction, or a failure of the electronic device. Therefore, it is important to cool the electronic component in order to prevent the temperature of the electronic component from exceeding the permissible upper-limit temperature.

Cooling apparatuses for cooling an electronic component (e.g., a CPU) include an air cooling type cooling apparatus and a water cooling type cooling apparatus. In the case where an electronic component generates a large amount of heat, the water cooling type cooling apparatus is often used. Hereinafter, the electronic component generating the large amount of heat will be referred to as a “heat generating component.”

A water cooling type cooling apparatus includes a heat receiving unit that is attached to the heat generating component, a heat radiating unit that is disposed at a place spaced away from the heat receiving unit, and a pump that is provided between the heat receiving section and the heat radiating unit to circulate cooling water.

Generally, the heat receiving unit is made of a metal having high heat conductivity, and a flow path is formed inside the heat receiving unit so as to allow the cooling water to flow therethrough. The heat radiating unit is also provided with, for example, a fin or a blower for heat radiation.

Heat generated from the heat generating component is transported to the heat radiating unit by the cooling water that passes through the heat receiving unit, and then is released from the heat radiating unit to the atmosphere. Herein, water or other thermal media used for transporting heat from the heat receiving unit to the heat radiating unit will be referred to as “cooling water.”

A centrifugal pump is used as the pump of the cooling apparatus. The centrifugal pump includes a casing that is provided with an inlet and an outlet, and an impeller that is disposed within the casing and is rotated by a motor. Further, the impeller includes a disc-shaped member called a shroud, and a plurality of blades that are radially disposed on the surface of the shroud. The central shaft of the shroud is connected to the motor.

In the water-cooling type cooling apparatus, when the pump breaks down during the operation of the electronic device, the heat generated from the heat generating component may not be transported to the heat radiating unit so that the heat generating component reaches a high temperature within a short period of time. Thus, the reduction in processing capability of the electronic device may be degradated or a heavy damage such as, for example, system down, may be caused.

In order to avoid such problems, it is considered to use a plurality of pumps and a plurality of electromagnetic valves such that the flow path of the cooling water is automatically switched so as to continuously circulate the cooling water by another pump even if one pump breaks down. However, this is problematic in that the number of components or pipes increases so that the miniaturization of the electronic device is hindered.

The followings are reference documents.

[Document 1] Japanese Laid-Open Utility Model Publication No. 62-024014,

[Document 2] Japanese Laid-Open Utility Model Publication No. 06-022159, and

[Document 3] Japanese Laid-Open Patent Publication No. 09-079171.

### SUMMARY

According to an aspect of the invention, a pump includes: an impeller including a rotary shaft and a plurality of blades extending radially from the rotary shaft, a cutout or a hole is formed in each of the blades; a casing housing the impeller therein; an inlet provided to the casing, a thermal medium flows in the casing through the inlet; and an outlet provided to the casing, the thermal medium flows out of the casing through the outlet.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A and 1B are schematic views illustrating an exemplary shroudless centrifugal pump;

FIGS. 2A and 2B are views illustrating an exemplary cooling apparatus using two centrifugal pumps;

FIG. 3 is a schematic view illustrating a cooling apparatus according to an embodiment;

FIGS. 4A and 4B are schematic views illustrating a structure of a centrifugal pump;

FIG. 5 is a perspective view of an impeller;

FIG. 6 is a perspective view illustrating an impeller of a pump according to Modification 1;

FIG. 7 is a perspective view illustrating an impeller of a pump according to Modification 2; and

FIG. 8 is a schematic view illustrating an exemplary electronic device that is provided with a cooling apparatus.

### DESCRIPTION OF EMBODIMENTS

Hereinafter, some particulars will be described to allow those skilled in the art to easily understand embodiments, prior to explaining the embodiments.

As described above, an impeller of a general centrifugal pump is provided with a shroud. However, in order to cope with the miniaturization of an electronic device, it is examined to use a shroudless centrifugal pump in a cooling apparatus of an electronic device.

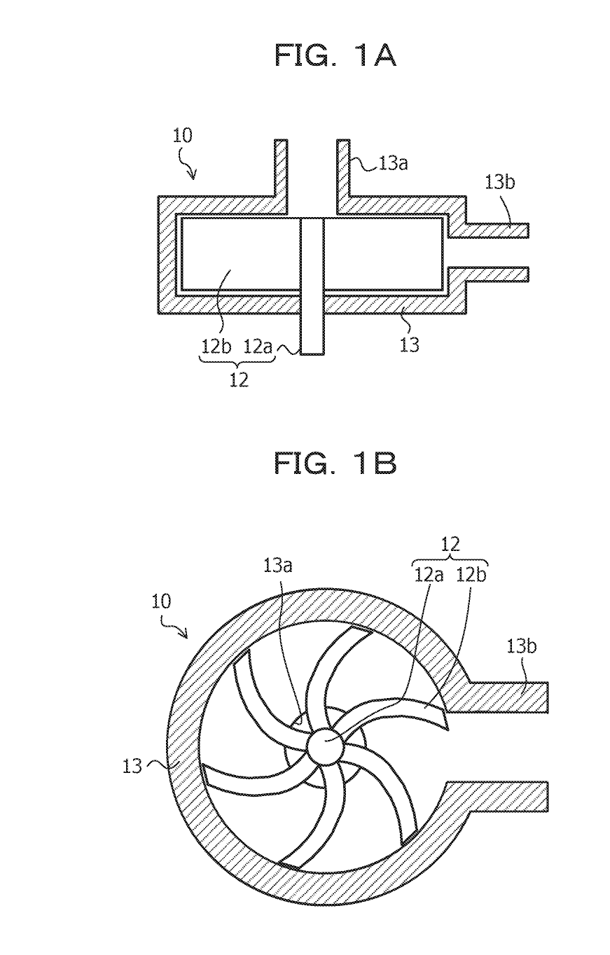

FIGS. 1A and 1B are schematic views illustrating an exemplary shroudless centrifugal pump. FIG. 1A illustrates a schematic horizontal cross- sectional view, and FIG. 1B illustrates a schematic vertical cross-section view of the centrifugal pump.

The centrifugal pump 10 illustrated in FIGS. 1A and 1B includes a casing 13 and an impeller 12 disposed within the casing 13.

The casing 13 is provided with an inlet 13a through which cooling water is introduced into the casing 13, and an outlet 13b through which the cooling water is discharged. Further, the impeller 12 includes a rotary shaft 12a and a plurality of blades 12b extending radially from the rotary shaft 12a.

The rotary shaft 12a is rotatably supported in the casing 13 through a bearing (not illustrated), and is connected to a motor (not illustrated). Further, the inlet 13a is formed at the center of a side surface of the casing 13, that is, a position corresponding to the rotary shaft 12a, and the outlet 13b is formed on the circumference of the casing 13.

When the impeller 12 rotates, a centrifugal force acts on the cooling water in the casing 13 in the radial direction of the impeller 12 so that the cooling water is discharged from the outlet 13b. Further, cooling water is introduced into the casing 13 from the inlet 13a by an amount that corresponds to the amount of the cooling water discharged from the outlet 13b.

In the above-mentioned centrifugal pump 10, when a large gap is present between the impeller 12 (wings 12b) and the casing 13, some of the cooling water pushed out by the impeller 12 passes through the gap between the impeller 12 and the casing 13 and returns to the inlet side. Consequently, in order to secure a desired water discharge amount, it is required to increase the number of rotations of the motor, and thus, power consumption is increased. In order to avoid such a problem, the gap between the impeller 12 (blades 12b) and the casing 13 is set as narrow as possible.

In a cooling apparatus that includes only one pump, when the pump breaks down, heat may not be transported from the heat receiving unit to the heat radiating unit. Therefore, it is considered to use a plurality of pumps so as to secure redundancy.

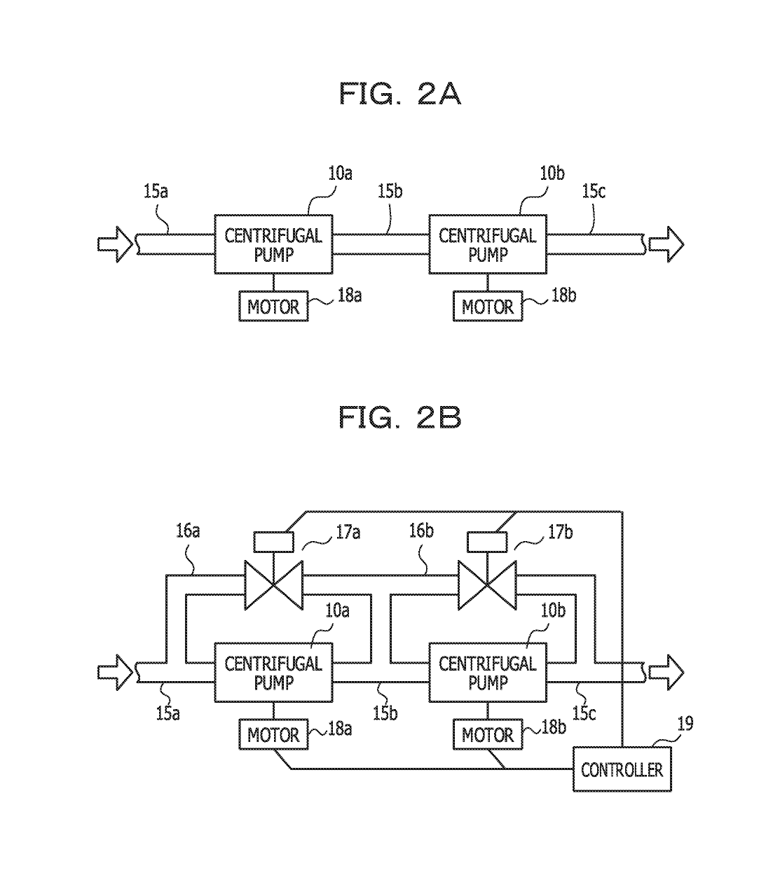

FIG. 2A is a view illustrating an exemplary cooling apparatus using two centrifugal pumps so as to ensure redundancy.

In the example illustrated in FIG. 2A, the centrifugal pumps 10a and 10b are connected in series between a pipe 15a connected to the heat receiving unit (not illustrated) and a pipe 15c connected to the heat radiating unit (not illustrated). That is, an inlet of the centrifugal pump 10a is connected to the pipe 15a, and an outlet of the centrifugal pump 10a is connected to a pipe 15b. Further, an inlet of the centrifugal pump 10b is connected to the pipe 15b, and an outlet thereof is connected to the pipe 15c.

The impeller of the centrifugal pump 10a is rotated by a motor 18a, while the impeller of the centrifugal pump 10b is rotated by a motor 18b.

Even if either of the centrifugal pump 10a or 10b breaks down in such a cooling apparatus, the cooling water may be circulated between the heat receiving unit and the heat radiating unit by the other centrifugal pump 10b or 10a. However, as described above, since the narrow gap is set between the impeller 12 and the casing 13 in each of the centrifugal pumps 10a and 10b, a flow path resistance increases abruptly when the impeller 12 of any one of the centrifugal pumps stops rotating. Therefore, the flow rate of cooling water discharged from the other centrifugal pump is considerably reduced.

FIG. 2B is a view illustrating another example of cooling apparatus using two centrifugal pumps so as to secure redundancy.

In the example illustrated in FIG. 2B, the centrifugal pumps 10a and 10b are connected in series between pipes 15a and 15c in the same manner as the example illustrated in FIG. 2A.

A bypass pipe 16a is installed between the pipes 15a and 15b. An electromagnetic valve 17a is connected to the bypass pipe 16a. In addition, a bypass pipe 16b is installed between the pipes 15b and 15c.

An electromagnetic valve 17b is connected to the bypass pipe 16b. When the centrifugal pumps 10a and 10b are normally operated, both the electromagnetic valves 17a and 17b are closed.

The impeller of the centrifugal pump 10a is rotated by a motor 18a, while the impeller of the centrifugal pump 10b is rotated by a motor 18b.

A controller 19 monitors the rotation of the motors 18a and 18b to open the electromagnetic valve of the bypass pipe of the centrifugal pump 10a or 10b that has broken down.

For example, when the centrifugal pump 10a (motor 18a) breaks down, the controller 19 opens the electromagnetic valve 17a. Thus, the cooling water bypasses the centrifugal pump 10a and flows in the centrifugal pump 10b, and a desired flow rate of cooling water may be supplied to the heat receiving unit by the centrifugal pump 10b.

However, the cooling apparatus illustrated in FIG. 2B is problematic in that the number of components or pipes is increased so that the miniaturization of the electronic device is hindered.

### Embodiment

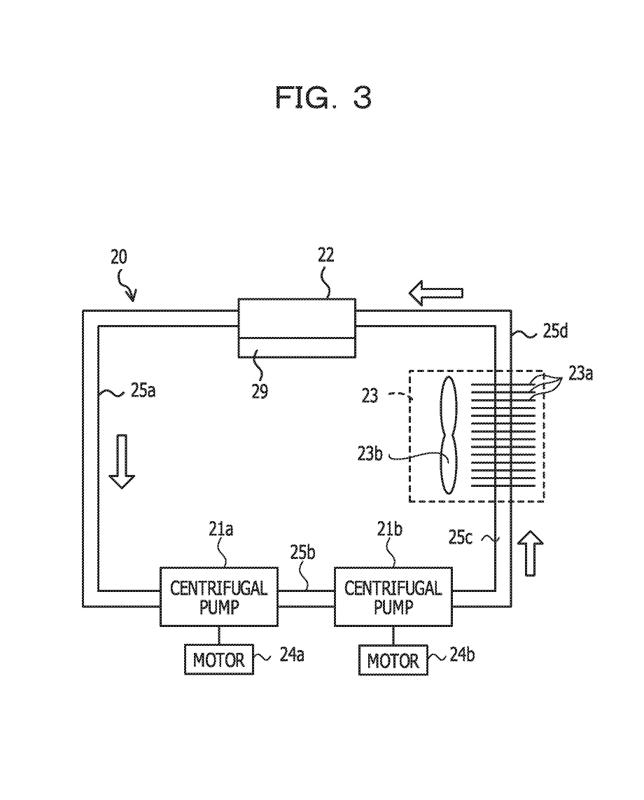

FIG. 3 is a schematic view illustrating a cooling apparatus according to an embodiment. Arrows of FIG. 3 indicate the flow direction of the cooling water.

In the example illustrated in FIG. 3, the cooling apparatus 20 according to the present embodiment includes two centrifugal pumps 21a and 21b, a heat receiving unit 22, and a heat radiating unit 23. The centrifugal pump 21a is driven by a motor 24a, while the centrifugal pump 21b is driven by a motor 24b.

The heat receiving unit 22 is made of a metal having high heat conductivity, and is thermally connected with a heat generating component (electronic component) 29 (e.g., CPU). A flow path is provided within the heat receiving unit to allow the cooling water to flow therethrough.

A water outlet of the heat receiving unit 22 and an inlet of the centrifugal pump 21a are connected to each other by a pipe 25a. Further, an outlet of the centrifugal pump 21a and an inlet of the centrifugal pump 21b are connected by a pipe 25b. Furthermore, an outlet of the centrifugal pump 21b and a water inlet of the heat radiating unit 23 are connected by a pipe 25c. A water outlet of the heat radiating unit 23 and a water inlet of the heat receiving unit 22 are connected by a pipe 25d.

A plurality of fins 23a is installed around a cooling water path of the heat radiating unit 23. Further, a blower 23b is installed in the vicinity of the fins 23a to cause air to flow between the fins 23a. Heat is transferred from the cooling water through the fins 23a to the air passing between the fins 23a, so that the temperature of the cooling water passing through the heat radiating unit 23 is lowered.

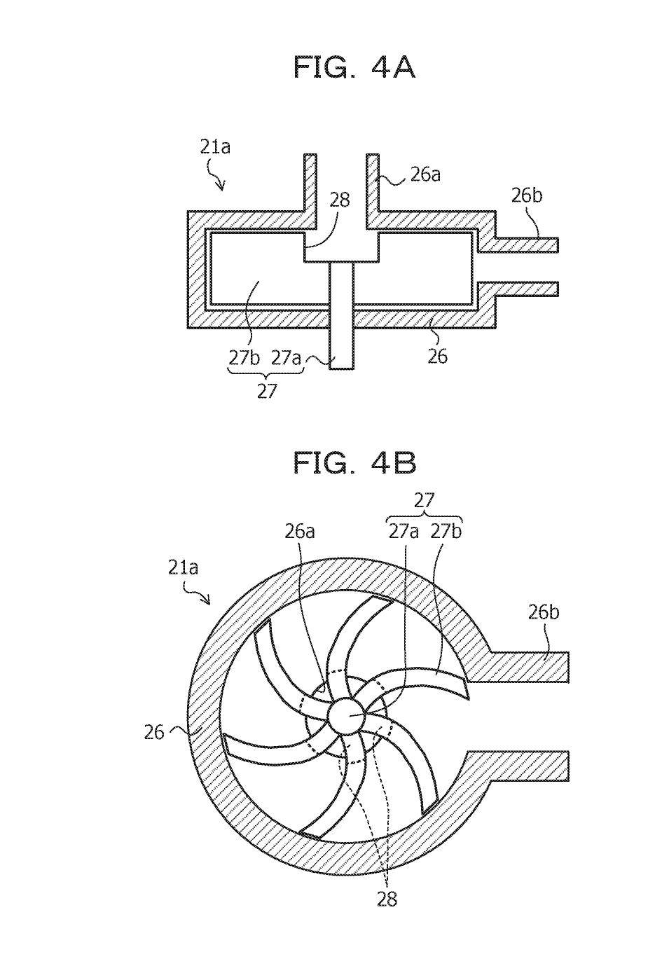

FIGS. 4A and 4B are schematic views illustrating the structure of the centrifugal pump 21a. FIG. 4A illustrates a schematic horizontal cross-sectional view of the centrifugal pump 21a, and FIG. 4B illustrates a schematic vertical cross-sectional view of the centrifugal pump 21a. Since the structure of the centrifugal pump 21b is the same as the centrifugal pump 21a, a detailed description thereof will be omitted herein.

The centrifugal pump 21a includes a casing 26 and an impeller 27 disposed in the casing 26. The casing 26 is provided with an inlet 26a through which cooling water is introduced into the casing 26 and an outlet 26b through which the cooling water is discharged. Further, the impeller 27 has a rotary shaft 27a and a plurality of blades 27b extending radially from the rotary shaft 27a.

The rotary shaft 27a is a cylindrical member, and is rotatably supported in the casing 26 through a bearing (not illustrated). The rotary shaft 27a is rotated by a motor 24a (see, e.g., FIG. 3).

The inlet 26a is formed at the center of a side surface of the casing 26, that is, a position corresponding to the rotary shaft 27a. Further, the outlet 26b is formed on a circumference of the casing 26. The inlet 26a of the centrifugal pump 21a is connected to the pipe 25a, while the outlet 26b of the centrifugal pump is connected to the pipe 25b.

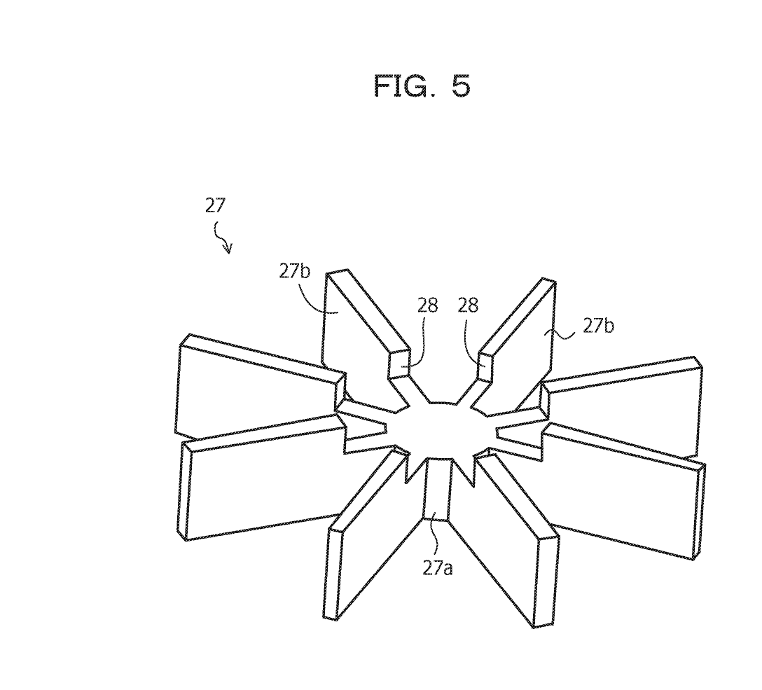

FIG. 5 is a perspective view of the impeller 27. According to the present embodiment, as illustrated in FIG. 5, a cutout 28 is formed in each blade 27b. Such a cutout 28 is formed at a position corresponding to the inlet 26a. Thus, cooling water introduced from the inlet 26a into the casing 21 may flow through the cutout 28 in the circumferential direction of the rotary shaft 27a.

When the impeller 27 rotates, a centrifugal force acts on the cooling water in the casing 26 in a radial direction of the impeller 27 so that the cooling water is discharged from the outlet 26b. Further, cooling water is introduced into the casing 26 from the inlet 26a by an amount that corresponds to the amount of the cooling water discharged from the outlet 26b.

Hereinafter, an operation of the cooling apparatus 20 according to the present embodiment will be described with reference to FIG. 3.

When the centrifugal pumps 21a and 21b are operated, cooling water is sequentially circulated from the heat receiving unit 22 through the pipe 25a, the centrifugal pump 21a, the pipe 25b, the centrifugal pump 21b, the pipe 25c, the heat radiating unit 23, the pipe 25d, and the heat receiving unit 22.

As described above, since the heat receiving unit 22 is thermally connected to the heat generating component 29, the heat generating component 29 is cooled by the cooling water that passes through the heat receiving unit 22. Further, the cooling water passing through the heat receiving unit 22 cools the heat generating component 29 so that the temperature of the cooling water rises.

The cooling water that has a temperature risen in the heat receiving unit 22 is sent to the water inlet of the heat radiating unit 23 through the pipe 25a, the centrifugal pump 21a, the pipe 25b, the centrifugal pump 21b, and the pipe 25c. Further, the cooling water is cooled by air sent from the blower 23b while passing through the heat radiating unit 23 so that the temperature of the cooling water is lowered. The cooling water that has a temperature lowered while passing through the heat radiating unit 23 is sent to the heat receiving unit 22 through the pipe 25d.

Thus, in the cooling apparatus 20 according to the present embodiment, the cooling water is circulated through the heat receiving unit 22, the centrifugal pumps 21a and 21b, and the heat radiating unit 23 in this order. Heat is transported from the heat receiving unit 22 to the heat radiating unit 23, so that in the temperature increase of the heat generating component 29 is avoided.

In this case, since the cooling water is circulated by the two centrifugal pumps 21a and 21b, the load of each centrifugal pump 21a, 21b is relatively small.

Here, it is assumed that any one of the centrifugal pump 21a, 21b breaks down. Here, it is assumed that the centrifugal pump 21a (motor 24a) breaks down and thus the impeller 27 stops rotating.

According to the present embodiment, as illustrated in FIGS. 4A, 4B and 5, the cutout 28 is formed in a portion of each blade 27b. Therefore, even if the impeller 27 does not rotate, the cooling water may flow from the inlet 26a to the outlet 26b through the cutout 28, and the flow path resistance is small between the inlet 26a and the outlet 26b.

Thus, even if the centrifugal pump 21a stops operating, the load of the centrifugal pump 21b is not significantly increased and a desired flow rate of cooling water may be circulated between the heat receiving unit 22 and the heat radiating unit 23 only by the centrifugal pump 21b.

The cooling apparatus illustrated in FIG. 2B requires the bypass pipes 16a and 16b and the electromagnetic valves 17a and 17b, whereas the cooling apparatus of the present embodiment does not require the bypass pipe and the electromagnetic valve. Consequently, the embodiment is advantageous in that component cost or installation cost is reduced and it is easy to cope with the miniaturization of the cooling apparatus.

Preferably, the size of the cutout 28 of each blade 27b is set such that a sectional area at a certain position of the cooling water path in the casing 26 is equal to or larger than a sectional area of the inlet 26a. The reason is as follows: when a portion smaller than the sectional area of the inlet 26a exists in the cooling water flow path in the casing 26, the flow rate of the cooling water is restricted at the portion and thereby the flow path resistance is increased.

Although it has been described in the above-described embodiments that the cutout 28 is formed in each blade 27b, the same effect as the foregoing embodiment may be obtained even if a hole is formed instead of the cutout 28.

(Modification 1)

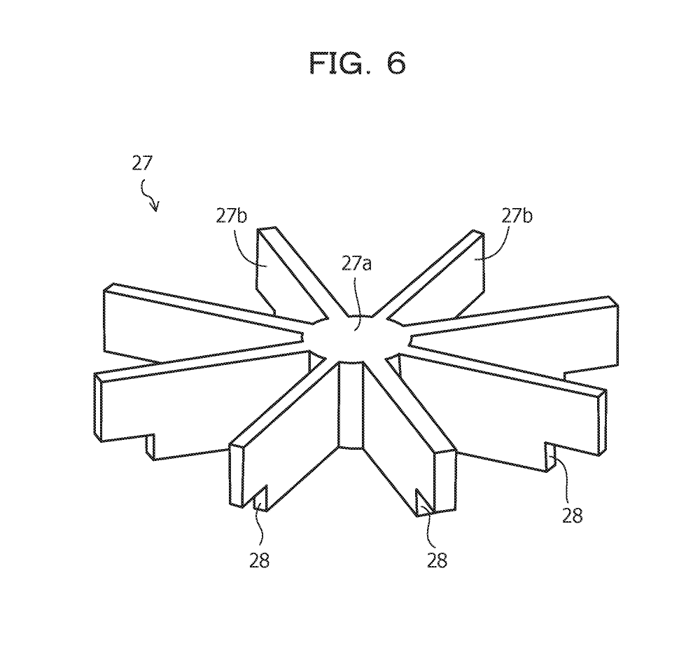

FIG. 6 is a perspective view illustrating an impeller of a pump according to Modification 1.

The pump of Modification 1 remains the same as the pumps 21a and 21b of the above-described embodiments except for the shape of the impeller. Thus, a duplicated description thereof will be omitted herein.

In the above-described embodiments, descriptions have been made on the example in which the cutout 28 is formed in an inner portion of each blade 27b of the impeller 27, that is, a portion corresponding to the inlet 26a. However, the same effect as the above-described embodiments even if the cutout 28 is formed in a distal end of each blade 27b as illustrated in FIG. 6.

(Modification 2)

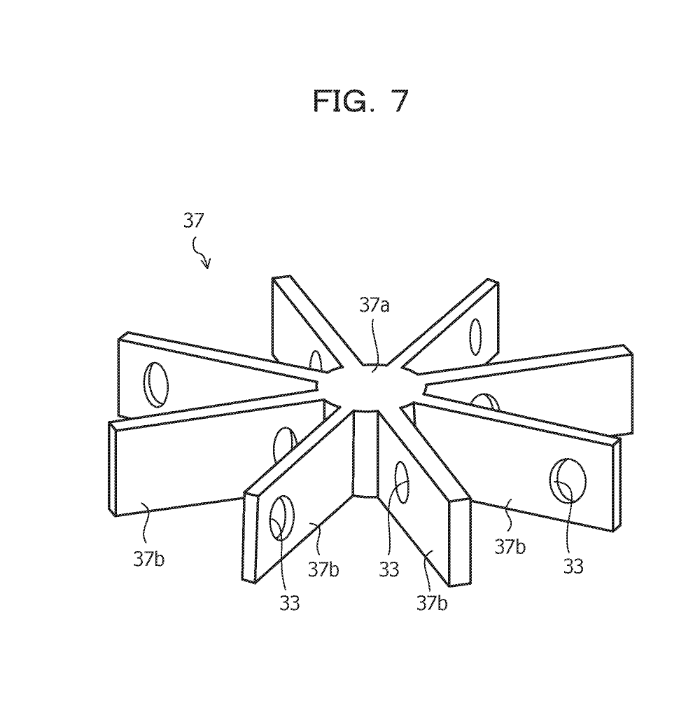

FIG. 7 is a perspective view illustrating an impeller of a pump according to Modification 2.

The pump of the second variant remains the same as the pumps 21a and 21b of the above-described embodiments except for the shape of the impeller. Thus, a duplicated description thereof will be omitted herein.

An impeller 37 of the pump of Modification includes blades 32a and 32b that are alternately arranged in a rotating direction of the rotary shaft 37a. Each blade 32a has a hole 33 in a distal end thereof, and each blade 32b has a hole 33 at a position adjacent to the rotary shaft 37a.

In the pump having such an impeller 37, it is also possible to reduce the flow path resistance between the inlet and the outlet small when the impeller 37 is stopped so that the same effect as the first embodiment may be obtained.

Further, when all the cutouts 28 are formed in the distal ends of the blades 27b as illustrated in FIG. 6, the blades 27 do not collide with the cooling water at the positions of the cutouts 28 even if the impeller 27 is rotated. Consequently, centrifugal force acting on the cooling water is small and the discharge amount of the pump is reduced. On the contrary, when the holes 33 are formed in different positions at neighboring blades 32a as illustrated in FIG. 7, the cooling water passing through the hole 33 of one blade 32a collides with the next blade 33 to impart a centrifugal force. As a result, the reduction in the discharge flow rate of the pump is suppressed.

(Electronic Device)

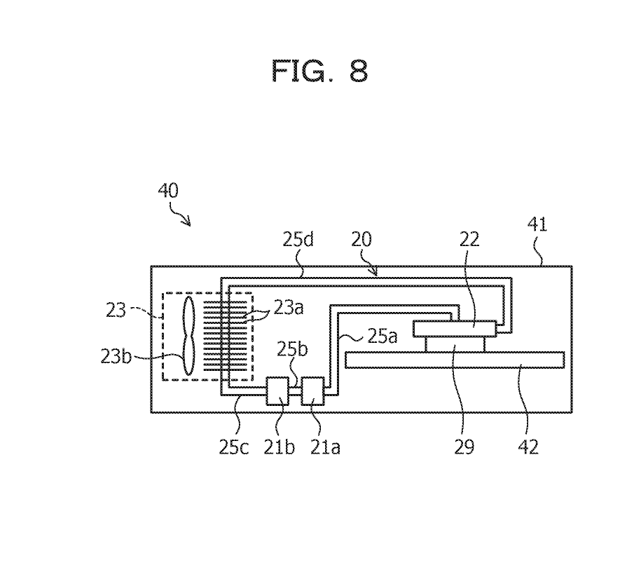

FIG. 8 is a schematic view illustrating an exemplary electronic device equipped with the above-described cooling apparatus.

An electronic device 40 of FIG. 8 includes a case 41, a circuit board 42 accommodated in the case 41, and a cooling apparatus 20.

A heat generating component (electronic component) 29 (e.g., a CPU) is mounted on the circuit board 42. As illustrated in FIG. 3, the cooling apparatus 20 includes the centrifugal pumps 21a and 21b, the heat receiving unit 22, the heat radiating unit 23, and the pipes 25a to 25d. Further, the heat receiving unit 22 is thermally connected to the heat generating component 29.

A plurality of fins 23a is installed in a cooling unit 23, and a blower 23b is disposed on an end of the case 41.

The electronic device 40 according to the present embodiment circulates cooling water between the heat receiving unit 22 and the heat radiating unit 23 by two centrifugal pumps 21a and 21b each having the blades 27b in which the cutouts 28 are formed, as illustrated in FIG. 5. Therefore, even if any one of the two pumps 21a and 21b breaks down, a sufficient amount of cooling water may be continuously supplied to the heat receiving unit 22, and the electronic device 40 may be continuously used without stopping the operation of the electronic device 40. As a result, the electronic device 40 according to the present embodiment is able to avoid the reduction in processing capability or system down due to the insufficient cooling of the heat generating component 29, and has high reliability.

Although the liquid cooling type cooling apparatus has been described herein with reference to FIG. 8, the technology of the disclosure is also applicable to a gas-liquid two-phase type cooling apparatus. In the gas-liquid two-phase type cooling apparatus, some liquid (thermal medium) is evaporated, and, for example, electronic components are cooled using evaporation heat.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. A pump comprising:
an impeller including a rotary shaft and a plurality of blades extending radially from the rotary shaft, a cutout or a hole is formed in each of the blades;
a casing housing the impeller therein;
an inlet provided to the casing, a thermal medium flows in the casing through the inlet; and
an outlet provided to the casing, the thermal medium flows out of the casing through the outlet.

2. The pump according to claim 1, wherein the cutout or the hole is formed at a position corresponding to the inlet.

3. The pump according to claim 1, wherein the cutout or the hole is formed at a distal end of each of the blades.

4. The pump according to claim 1, wherein cutouts or holes of neighboring blades in a rotating direction of the impeller are positioned to be staggered in a radial direction of the impeller.

5. The pump according to claim 1, wherein a sectional area at a certain position of a thermal-medium flow path in the casing is equal to or larger than a sectional area of the inlet.

6. A cooling apparatus comprising:
a heat receiving unit thermally coupled to a heat generating component;
a heat radiating unit; and
first and second pumps coupled in series to each other so as to circulate a thermal medium between the heat receiving unit and the heat radiating unit,
wherein at least one of the first and second pumps includes:
an impeller including a rotary shaft and a plurality of blades extending radially from the rotary shaft, a cutout or a hole is formed in each of the blades;
a casing housing the impeller therein;
an inlet provided to the casing, a thermal medium flows in the casing through the inlet; and
an outlet provided to the casing, the thermal medium flows out of the casing through the outlet.

7. An electronic device comprising:
a case;
an electronic component disposed in the case;
a heat receiving unit thermally coupled to the electronic component;
a heat radiating unit; and
first and second pumps coupled in series to each other so as to circulate a thermal medium between the heat receiving unit and the heat radiating unit,
wherein at least one of the first and second pumps includes:
an impeller including a rotary shaft and a plurality of blades extending radially from the rotary shaft, a cutout or a hole is formed in each of the blades;
a casing housing the impeller therein;
an inlet provided to the casing, a thermal medium flows in the casing through the inlet; and
an outlet provided to the casing, the thermal medium flows out of the casing through the outlet.
